(19) United States
(12) Patent Application Publication
(10) Pub. No.: US 2025/0364006 A1
(43) Pub. Date: Nov. 27, 2025

(54) High Unidirectional Anisotropy Constant Amorphous Shield Layer For Shield Application

(71) Applicant: Headway Technologies, Inc., Milpitas, CA (US)

(72) Inventors: Sangmun Oh, San Jose, CA (US); Shohei Kawasaki, Sunnyvale, CA (US); Hui-Chuan Wang, Pleasanton, CA (US); Huadong Gan, Union City, CA (US); Kunliang Zhang, Fremont, CA (US)

(21) Appl. No.: 18/674,422

(22) Filed: May 24, 2024

(51) Int. Cl. G11B 5/39; H10N 50/01; H10N 50/10; H10N 50/85

(52) U.S. Cl. CPC G11B 5/3909; G11B 5/3912; H10N 50/01; H10N 50/10; H10N 50/85

(57) ABSTRACT

The present embodiments relate to a free layer of a sensor (e.g., a tunneling magneto-resistive (TMR) sensor) for a cobalt-iron (CoFe) and tantalum (Ta) (CFT) to form a layer with a small Hc. A shield material as described with the present embodiments can include a cobalt-iron (CoFe) and tantalum (Ta) (CoFe-25 at %)-Ta material that can give a high magnetic moment, amorphous (low Hc), high Hₑₓ, high Jₖ.

### TECHNICAL FIELD

Embodiments of the invention relate to the field of electro-mechanical data storage devices. More particularly, embodiments of the invention relate to free layer of a tunneling magneto-resistive (TMR) sensor with a cobalt-iron (CoFe) and tantalum (Ta) (CFT) material.

### BACKGROUND

A magnetic recording medium (e.g., a magnetic disk) can store magnetic bits representing digital data. A magneto-resistive writer can be part of a hard disk drive (HDD) to write digital data to the magnetic recording medium.

As an overall amount of digital data being stored on HDD devices increases, there is an increasing demand for increased data capacity of HDD devices. One technique to increase data capacity for an HDD can include heat-assisted magnetic recording (HAMR) or microwave-assisted magnetic recording (MAMR). HAMR and MAMR techniques increase the density of HDDs by manipulating a portion of the magnetic recording medium, which can enhance write performance of the write head to the magnetic recording medium.

FIG. 1 is a perspective view of a prior art head arm assembly 100, according to some embodiments of the present disclosure. Referring to FIG. 1, a head arm assembly (or Head Gimbal Assembly (HGA)) 100 includes a magnetic recording head 101 comprised of a slider and a PMR writer structure formed thereon, and a suspension 103 that elastically supports the magnetic recording head. The suspension has a plate spring-like load beam 222 formed with stainless steel, a flexure 104 provided at one end portion of the load beam, and a base plate 224 provided at the other end portion of the load beam. The slider portion of the magnetic recording head is joined to the flexure, which gives an appropriate degree of freedom to the magnetic recording head. A gimbal part (not shown) for maintaining a posture of the magnetic recording head at a steady level is provided in a portion of the flexure to which the slider is mounted.

HGA 100 is mounted on an arm 230 formed in the head arm assembly 103. The arm moves the magnetic recording head 101 in the cross-track direction y of the magnetic recording medium 140. One end of the arm is mounted on base plate 224. A coil 231 that is a portion of a voice coil motor is mounted on the other end of the arm. A bearing part 233 is provided in the intermediate portion of arm 230. The arm is rotatably supported using a shaft 234 mounted to the bearing part 233. The arm 230 and the voice coil motor that drives the arm configure an actuator.

Next, a side view 200 of a head stack assembly (FIG. 2) and a plan view 300 of a magnetic recording apparatus (FIG. 3) wherein the magnetic recording head 101 is incorporated are depicted. The head stack assembly 250 is a member to which a plurality of HGAs (HGA 100-1 and second HGA 100-2 are at outer positions while HGA 100-3 and HGA 100-4 are at inner positions) is mounted to arms 230-1, 230-2, respectively, on carriage 251. A HGA is mounted on each arm at intervals so as to be aligned in the perpendicular direction (orthogonal to magnetic medium 140). The coil portion (231 in FIG. 1) of the voice coil motor is mounted at the opposite side of each arm in carriage 251. The voice coil motor has a permanent magnet 263 arranged at an opposite position across the coil 231.

With reference to FIG. 3, the head stack assembly 250 is incorporated in a magnetic recording apparatus 260. The magnetic recording apparatus has a plurality of magnetic media 140 mounted to spindle motor 261. For every magnetic recording medium, there are two magnetic recording heads arranged opposite one another across the magnetic recording medium. The head stack assembly and actuator except for the magnetic recording heads 101 correspond to a positioning device, and support the magnetic recording heads, and position the magnetic recording heads relative to the magnetic recording medium. The magnetic recording heads are moved in a cross-track of the magnetic recording medium by the actuator. The magnetic recording head records information into the magnetic recording media with a PMR writer element (not shown) and reproduces the information recorded in the magnetic recording media by a magneto-resistive (MR) sensor element (not shown).

Further, tunneling magneto-resistive (TMR) sensors with stable shield biasing can be important for various high density magnetic recording applications. The TMR sensor can include any of a free layer, barrier layer, and a pin layer. The magnetization direction of the pin layer can be configured to be fixed and a magnetization direction of the free layer can change due to an external magnetic field direction. Further, an electrical resistance of the TMR sensor can decrease when magnetization directions of the pin layer and free layer are in parallel, and the electrical resistance of the TMR sensor can increase when magnetization directions of the pin layer and free layer are anti-parallel. A disk drive can include a write head to interact with a magnetic recording medium to read and write digital data to the magnetic recording medium. As the amount of digital data is required to be stored increases and with an increase in data aerial density of hard disk drive (HDD) writing, both the write head and digital data written to the magnetic recording medium can generally be made smaller.

Accordingly, further developments in this field are needed.

### SUMMARY

The present embodiments relate to a free layer of a sensor (e.g., a tunneling magneto-resistive (TMR) sensor) for a cobalt-iron (CoFe) and tantalum (Ta) (CFT) to form a layer with a small He. A shield material as described with the present embodiments can include a cobalt-iron (CoFe) and tantalum (Ta) (CoFe-25 at %)-Ta material that can give a high magnetic moment, amorphous (low Hc), high Hₑₓ, high Jₖ.

In a first example embodiment, a tunneling magneto-resistive (TMR) sensor is described. The sensor can include a free layer comprising a combination of Cobalt-Iron (CoFe) and Tantalum (Ta) (CFT). The free layer comprising CFT can be configured to provide an increased magnetic moment, amorphous (low Hx), high Hex, and a high Jk. The sensor can also include a barrier layer and a pin layer.

In some instances, the sensor can include a dopant to the free layer. The dopant can include any of hafnium (Hf), Ta, Yttrium (Y), zirconium (Zr), niobium (Nb), molybdenum (Mo), tungsten (W), titanium (Ti), and/or silicon (Si).

In some instances, the composition of the dopant can range between 0-20 percent of the free layer.

In some instances, the barrier layer comprises an electrical insulating material.

In some instances, the barrier layer comprises any of magnesium oxide (MgO), aluminum oxide (AlOx), titanium oxide (TiOx), and/or zinc oxide (ZnOx).

In another example embodiment, a method of manufacturing a TMR sensor is provided. The method can include providing a free layer comprising a combination of Cobalt-Iron (CoFe) and Tantalum (Ta) (CFT). The method can also include doping the free layer with a dopant.

In some instances, the method can also include disposing a barrier layer adjacent to the free layer and disposing a pin layer adjacent to the barrier layer. A magnetization direction of the pin layer can be configured to be fixed and a magnetization direction of the free layer can change due to an external magnetic field direction.

In some instances, the dopant can include any of: hafnium (Hf), Ta, Yttrium (Y), zirconium (Zr), niobium (Nb), molybdenum (Mo), tungsten (W), titanium (Ti), and/or silicon (Si).

In some instances, the composition of the dopant can range between 0-20 percent of the free layer.

In some instances, the barrier layer comprises an electrical insulating material.

In some instances, the barrier layer comprises any of magnesium oxide (MgO), aluminum oxide (AlOx), titanium oxide (TiOx), and/or zinc oxide (ZnOx).

In some instances, the method can also include applying a current to form an external magnetic field to the TMR sensor. An electrical resistance of the TMR sensor can decrease when magnetization directions of the pin layer and free layer are in parallel, and the electrical resistance of the TMR sensor increases when magnetization directions of the pin layer and free layer are anti-parallel.

In another example embodiment, a device is provided. The device can include a free layer comprising a combination of Cobalt-Iron (CoFe) and Tantalum (Ta) (CFT). The free layer can be doped by a dopant. The device can also include a barrier layer and a pin layer. A magnetization direction of the pin layer can be configured to be fixed and a magnetization direction of the free layer can change due to an external magnetic field direction. An electrical resistance of the TMR sensor can decrease when magnetization directions of the pin layer and free layer are in parallel. The electrical resistance of the TMR sensor can increase when magnetization directions of the pin layer and free layer are anti-parallel.

In some instances, the dopant can include any of: hafnium (Hf), Ta, Yttrium (Y), zirconium (Zr), niobium (Nb), molybdenum (Mo), tungsten (W), titanium (Ti), and/or silicon (Si).

In some instances, the composition of the dopant can range between 0-20 percent of the free layer.

In some instances, the barrier layer comprises an electrical insulating material.

In some instances, the barrier layer comprises any of magnesium oxide (MgO), aluminum oxide (AlOx), titanium oxide (TiOx), and/or zinc oxide (ZnOx).

In some instances, the device is a tunneling magneto-resistive (TMR) sensor configured to be part of a hard disk drive system.

Other features and advantages of embodiments of the present invention will be apparent from the accompanying drawings and from the detailed description that follows.

### BRIEF DESCRIPTION OF THE DRAWINGS

Embodiments of the present invention are illustrated by way of example and not limitation in the figures of the accompanying drawings, in which like references indicate similar elements and in which:

FIG. 1 is a perspective view of a head arm assembly, according to prior art embodiments.

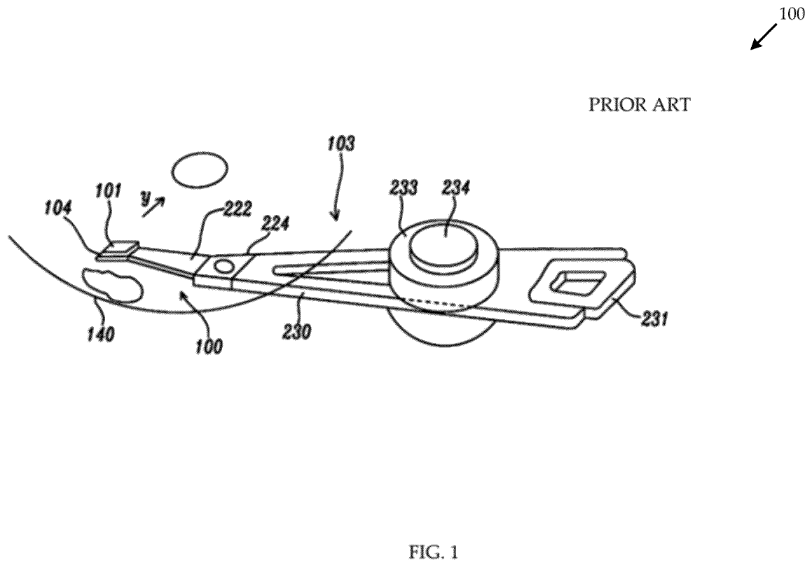

FIG. 2 is side view of a head stack assembly, according to prior art embodiments.

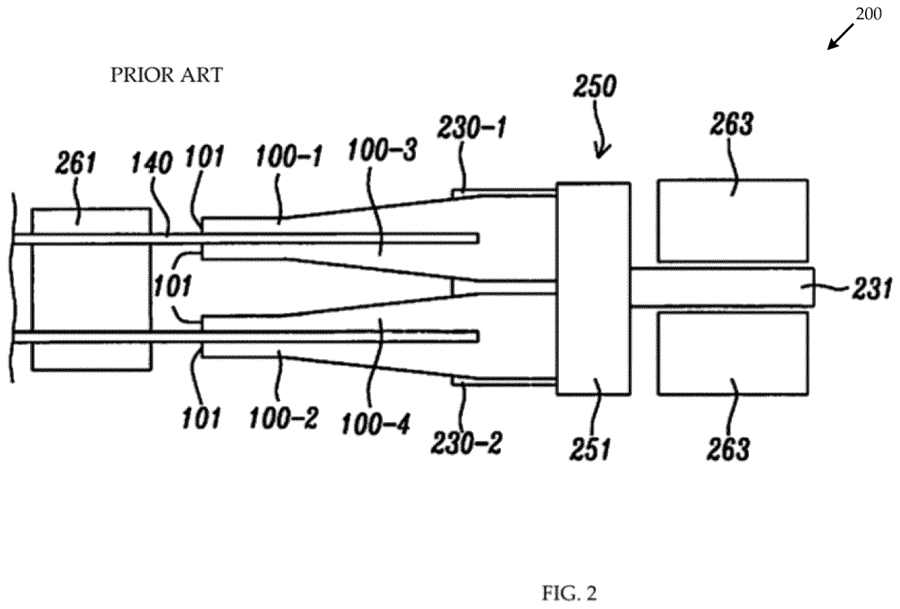

FIG. 3 is a plan view of a magnetic recording apparatus, according to prior art embodiments.

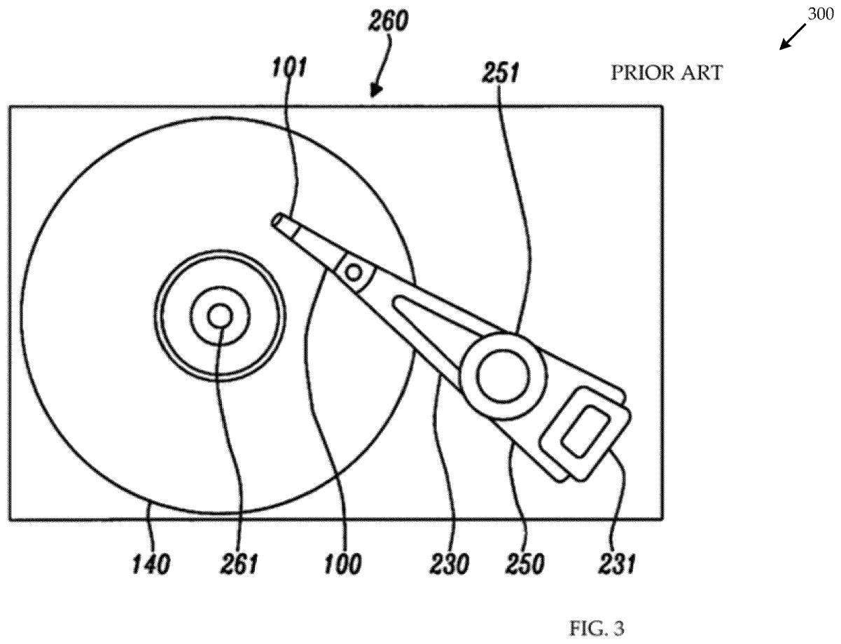

FIG. 4 illustrates an example TMR sensor according to an embodiment.

FIG. 5 is a graphical representation of an oersted (Oe) field of various shield types with respect to a flux according to an embodiment.

FIG. 6 is a graphical illustration of a He of various shield designs in relation to an anisotropy constant Jₖ according to an embodiment.

### DETAILED DESCRIPTION

Tunneling magneto-resistive (TMR) sensors with stable shield biasing can be important for various high density magnetic recording applications. Particularly, a shield material as described herein, such as a cobalt-iron (CoFe) and Tantalum (Ta) (CFT) shield, can have a high magnetic moment and an amorphous structure can be used as part of a shield layer.

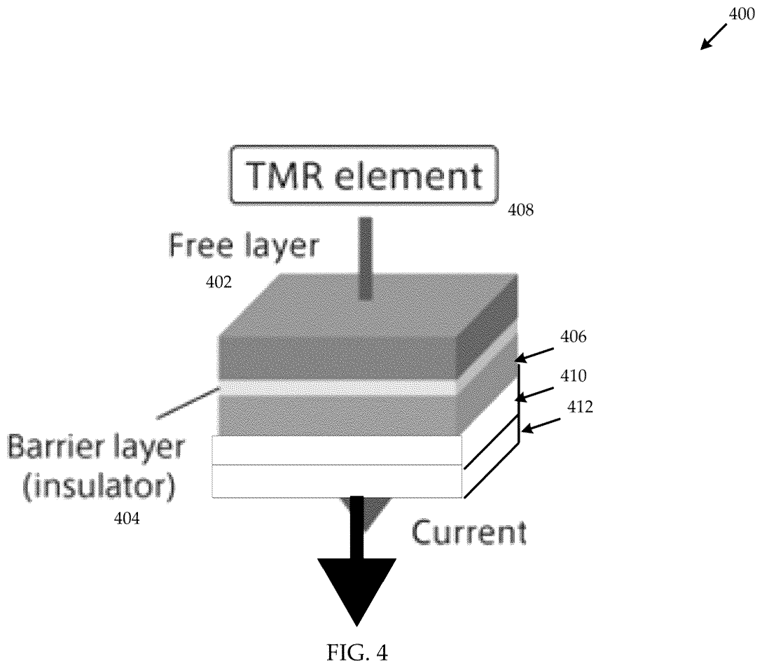

FIG. 4 illustrates an example TMR sensor 400. As shown in FIG. 4, the TMR sensor 400 can include a free layer 402, a barrier layer 404, and a pin layer 406. The free layer 402 can include a soft magnetic material as described herein. A barrier layer 404 can be disposed between the free layer 402 and pin layer 406. The barrier layer can be made of a thin insulator of 1 to 2 nm and can be sandwiched between two ferromagnetic layers (e.g., the free layer and pin layer).

The electrical resistance of the TMR element 408 can change along with a change in the free layer 402. The electrical resistance can become the smallest when the magnetization directions of the pin layer 406 and free layer 402 are parallel, causing a large current to flow into the barrier layer 404. When the magnetization directions are antiparallel, the resistance can become extremely large, and almost no current may flow into the barrier layer 404.

In many instances, a high magnetic moment can be desirable with a free layer (or a shield layer), as a unidirectional anisotropy constant (Jₖ) can generally be proportional to the moment.

Jₖ(erg/cm²)=Hₑₓ*Mₛ*t

A shield material having an amorphous state can also be important, as the shield can have a small coercivity (H_{c}) as well as low crystalline anisotropy constant for fast domain wall motion.

An example of another shield material can include a Permalloy based shield (NF). The NF shield can have a drawback in that the Jₖ may not be high enough due to NF's Face-Centered-Cubic (FCC) crystalline structure in nature. Since a Jₖ of NF with Iridium (IR) and Manganese (MN) (NF/IrMn) (IrMn layer 412) can be small, an insertion layer (CF) (insertion layer 410) between IrMn and NF can be used. However, due to under layer effect on NF(FCC), an CF (BCC) insertion effect can be limited.

In many cases, a drawback of a NF-based shield is that a high failure rate of a shield Reverse Magnet Initialization (sRMI) test can be observed. This can be caused by weak Jₖ or domain wall motion pinning, particularly when the device size decreases. Thus, having a high Jₖ with amorphous state can be a prerequisite for improving sRMI robustness.

The present embodiments relate to a co-sputtering process that can enable two or more target materials are simultaneously sputtered onto a substrate. This process can allow for composite thin film with high composition control. The co-sputtering process can allow for a cobalt-iron (CoFe) and tantalum (Ta) (CFT) to form an amorphous layer (e.g., a free layer of a TMR sensor) with a small He, which the material is referred to here as Co—Fe—Ta (CFT). A shield material as described with the present embodiments can include a cobalt-iron (CoFe) and tantalum (Ta) (CoFe-25 at %)-Ta material that can give a high magnetic moment, amorphous (low Hc), high Hₑₓ of around 300 Oe, high Jₖ of around 0.34 erg/cm².

Further, any of hafnium (Hf), Ta, Yttrium (Y), zirconium (Zr), niobium (Nb), molybdenum (Mo), tungsten (W), titanium (Ti), and/or silicon (Si) can be used as the dopant to CoFex (where x=0˜100 at %) layer for shield material. The composition of Hf, Ta, Y, Zr, Nb, Mo W, Ti, Si-dopant can range from 0˜20 at %. The shield material as described herein can be used for TMR sensors with various barrier layers, such as magnesium oxide (MgO), aluminum oxide (AlOx), titanium oxide (TiOx), and/or zinc oxide (ZnOx).

In some instances, a microstructure of CFT can be sensitive to an amount of Ta, the Ta amount can be monitored by changing sputtering power between a CoFe (CF) and Ta target via a co-sputtering process.

Further, Scanning Transmission Electron Microscopy Energy Dispersive Spectroscopy (STEM-EDS) results can show that Ta ˜5% across the film thickness in CFT layer. For film structure evaluation, Grazing Incidence X-Ray Diffraction—(GIXRD) can show that a microstructure of CFT can be amorphous.

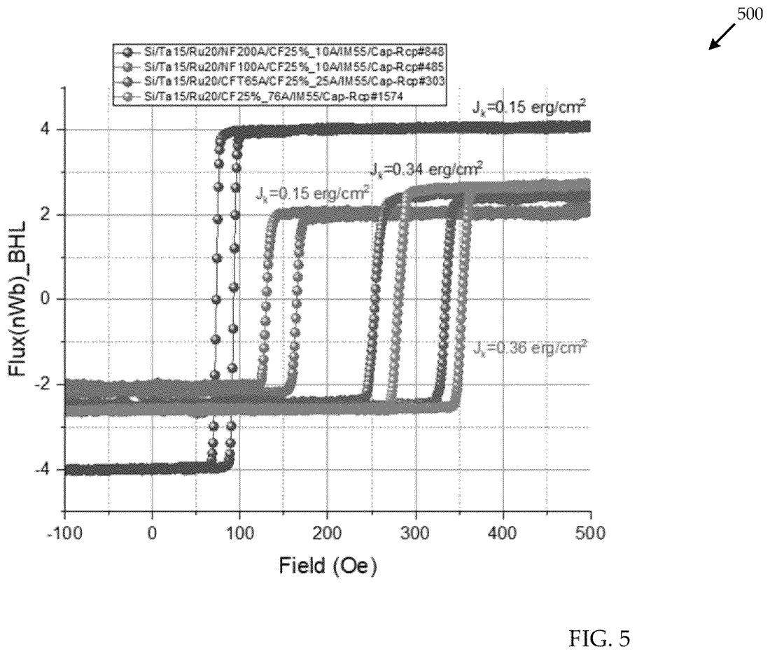

FIG. 5 is a graphical representation 500 of an oersted (Oe) field of various shield types with respect to a flux. As shown in FIG. 5, a Jₖ value for a shield as described herein can improve significantly from another design (e.g., POR), with a NF base shield of ˜0.15 erg/cm² to that of the CFT base shield of ˜0.34 erg/cm². The shield can include a greater sRMI robustness at least in part due to high Hₑₓ as well as a high Jₖ.

FIG. 5 further illustrates that the Jₖ value can be improved significantly from POR (NF base shield) ˜0.15 erg/cm² to ˜0.34 erg/cm² (CFT base shield). The CFT-Jₖ can also be compared with CF-Jₖ (known as maximum Jₖ system). CFT-Jₖ can be around 0.34 erg/cm² and CF-Jₖ can be around 0.36 erg/cm². A slightly smaller CFT-Jₖ compared to CF-Jₖ can be caused by partial crystalline island on CFT film as shown by TEM. CFT-Jₖ can also be almost double as NF-Jₖ and CFT-Jₖ which can be similar with maximum Jₖ system (CF).

In many instances, as sRMI robustness can be closely related to unidirectional anisotropy constant, a better sRMI robustness can be expected at least in part due to low He (e.g., of around 10 Oe), high Hₑₓ as well as high Jₖ.

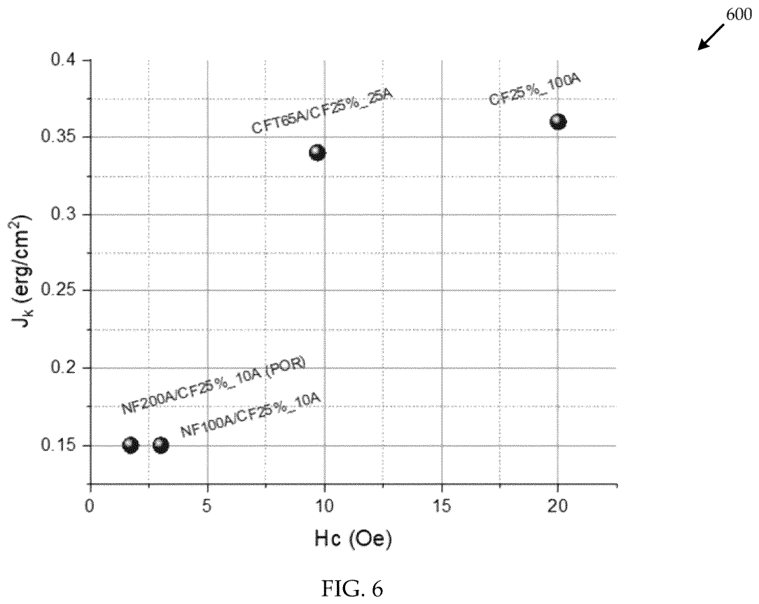

FIG. 6 is a graphical illustration 600 of a He of various shield designs in relation to an anisotropy constant Jₖ. As shown in FIG. 6, an amorphous CFT base shield can have a stronger stitching process tolerance. After stitching, Jk can still be high due to its amorphous structure.

FIG. 6 can also show the benefit of using CFT amorphous layer during stitching for ex-situ process. When compared to an in-situ process, ex-situ process can show a lower Jk due to stitching damage.

Further, stitching damage can be higher for crystalline structure, such as CF, which can show a long range order. The CFT's amorphous layer can show lower Jₖ drop by stitching process. Thus, after stitching process, CFT and CF can show the same Jₖ. Considering process complexities, having a good tolerance against stitching process can also be beneficial for having a CFT amorphous shield.

Thus, the CFT shield layer as described herein can have a high Hₑₓ, high Jₖ, amorphous, high magnetic moment as well as process-friendly materials against stitching process. By using CTF shield, the robustness of sRMI can be improved. Further, the CTF material can be fabricated with various target configurations.

In a first example embodiment, a tunneling magneto-resistive (TMR) sensor is described. The sensor can include a free layer comprising a combination of Cobalt-Iron (CoFe) and Tantalum (Ta) (CFT). The free layer comprising CFT can be configured to provide an increased magnetic moment, amorphous (low Hx), high Hex, and a high Jk. The sensor can also include a barrier layer and a pin layer.

In some instances, the sensor can include a dopant to the free layer. The dopant can include any of: hafnium (Hf), Ta, Yttrium (Y), zirconium (Zr), niobium (Nb), molybdenum (Mo), tungsten (W), titanium (Ti), and/or silicon (Si).

In some instances, the composition of the dopant can range between 0-20 percent of the free layer.

In some instances, the barrier layer comprises an electrical insulating material.

In some instances, the barrier layer comprises any of magnesium oxide (MgO), aluminum oxide (AlOx), titanium oxide (TiOx), and/or zinc oxide (ZnOx).

In another example embodiment, a method of manufacturing a TMR sensor is provided. The method can include providing a free layer comprising a combination of Cobalt-Iron (CoFe) and Tantalum (Ta) (CFT). The method can also include doping the free layer with a dopant.

In some instances, the method can also include disposing a barrier layer adjacent to the free layer and disposing a pin layer adjacent to the barrier layer. A magnetization direction of the pin layer can be configured to be fixed and a magnetization direction of the free layer can change due to an external magnetic field direction.

In some instances, the dopant can include any of: hafnium (Hf), Ta, Yttrium (Y), zirconium (Zr), niobium (Nb), molybdenum (Mo), tungsten (W), titanium (Ti), and/or silicon (Si).

In some instances, the composition of the dopant can range between 0-20 percent of the free layer.

In some instances, the barrier layer comprises an electrical insulating material.

In some instances, the barrier layer comprises any of magnesium oxide (MgO), aluminum oxide (AlOx), titanium oxide (TiOx), and/or zinc oxide (ZnOx).

In some instances, the method can also include applying a current to form an external magnetic field to the TMR sensor. An electrical resistance of the TMR sensor can decrease when magnetization directions of the pin layer and free layer are in parallel, and the electrical resistance of the TMR sensor increases when magnetization directions of the pin layer and free layer are anti-parallel.

In another example embodiment, a device is provided. The device can include a free layer comprising a combination of Cobalt-Iron (CoFe) and Tantalum (Ta) (CFT). The free layer can be doped by a dopant. The device can also include a barrier layer and a pin layer. A magnetization direction of the pin layer can be configured to be fixed and a magnetization direction of the free layer can change due to an external magnetic field direction. An electrical resistance of the TMR sensor can decrease when magnetization directions of the pin layer and free layer are in parallel. The electrical resistance of the TMR sensor can increase when magnetization directions of the pin layer and free layer are anti-parallel.

In some instances, the dopant can include any of: hafnium (Hf), Ta, Yttrium (Y), zirconium (Zr), niobium (Nb), molybdenum (Mo), tungsten (W), titanium (Ti), and/or silicon (Si).

In some instances, the composition of the dopant can range between 0-20 percent of the free layer.

In some instances, the barrier layer comprises an electrical insulating material.

In some instances, the barrier layer comprises any of magnesium oxide (MgO), aluminum oxide (AlOx), titanium oxide (TiOx), and/or zinc oxide (ZnOx).

In some instances, the device is a tunneling magneto-resistive (TMR) sensor configured to be part of a hard disk drive system.

It will be understood that terms such as “top,” “bottom,” “above,” “below,” and x-direction, y-direction, and z-direction as used herein as terms of convenience that denote the spatial relationships of parts relative to each other rather than to any specific spatial or gravitational orientation. Thus, the terms are intended to encompass an assembly of component parts regardless of whether the assembly is oriented in the particular orientation shown in the drawings and described in the specification, upside down from that orientation, or any other rotational variation.

It will be appreciated that the term “present invention” as used herein should not be construed to mean that only a single invention having a single essential element or group of elements is presented. Similarly, it will also be appreciated that the term “present invention” encompasses a number of separate innovations, which can each be considered separate inventions. Although the present invention has been described in detail with regards to the preferred embodiments and drawings thereof, it should be apparent to those skilled in the art that various adaptations and modifications of embodiments of the present invention may be accomplished without departing from the spirit and the scope of the invention. Accordingly, it is to be understood that the detailed description and the accompanying drawings as set forth hereinabove are not intended to limit the breadth of the present invention, which should be inferred only from the following claims and their appropriately construed legal equivalents.

What is claimed is:

1. A tunneling magneto-resistive (TMR) sensor comprising:
a free layer comprising a combination of Cobalt-Iron (CoFe) and Tantalum (Ta) (CFT), wherein the free layer comprising CFT is configured to provide an increased magnetic moment, a magnetic coercivity (Hc) of around 3 Oersted (Oe), an external magnetic field (Hₑₓ) of around 90 Oe, and a surface tension (Jₖ) of above 0.3 Erg per square centimeter (erg/cm²);
a barrier layer; and
a pin layer.

2. The TMR sensor of claim 1, further comprising a dopant to the free layer, the dopant comprising any of: hafnium (Hf), Ta, Yttrium (Y), zirconium (Zr), niobium (Nb), molybdenum (Mo), tungsten (W), titanium (Ti), and/or silicon (Si).

3. The TMR sensor of claim 2, wherein the composition of the dopant can range between 0-20 percent of the free layer.

4. The TMR sensor of claim 1, wherein the barrier layer comprises an electrical insulating material.

5. The TMR sensor of claim 4, wherein the barrier layer comprises any of magnesium oxide (MgO), aluminum oxide (AlOx), titanium oxide (TiOx), and/or zinc oxide (ZnOx).

6. A method of manufacturing a TMR sensor comprising:
providing a free layer comprising a combination of Cobalt-Iron (CoFe) and Tantalum (Ta) (CFT); and
doping the free layer with a dopant.

7. The method of claim 6, further comprising:
disposing a barrier layer adjacent to the free layer; and
disposing a pin layer adjacent to the barrier layer, wherein a magnetization direction of the pin layer is configured to be fixed and a magnetization direction of the free layer is configured to change due to an external magnetic field direction.

8. The method of claim 6, wherein the dopant comprising any of: hafnium (Hf), Ta, Yttrium (Y), zirconium (Zr), niobium (Nb), molybdenum (Mo), tungsten (W), titanium (Ti), and/or silicon (Si).

9. The method of claim 8, wherein the composition of the dopant can range between 0-20 percent of the free layer.

10. The method of claim 6, wherein the barrier layer comprises an electrical insulating material.

11. The method of claim 10, wherein the barrier layer comprises any of magnesium oxide (MgO), aluminum oxide (AlOx), titanium oxide (TiOx), and/or zinc oxide (ZnOx).

12. The method of claim 6, further comprising:
applying a current to form an external magnetic field to the TMR sensor, wherein an electrical resistance of the TMR sensor decreases when magnetization directions of the pin layer and free layer are in parallel, and wherein the electrical resistance of the TMR sensor increases when magnetization directions of the pin layer and free layer are anti-parallel.

13. A device comprising:
a free layer comprising a combination of Cobalt-Iron (CoFe) and Tantalum (Ta) (CFT), wherein the free layer is doped by a dopant;
a barrier layer; and
a pin layer, wherein a magnetization direction of the pin layer is configured to be fixed and a magnetization direction of the free layer can change due to an external magnetic field direction, and wherein an electrical resistance of the TMR sensor decreases when magnetization directions of the pin layer and free layer are in parallel, and wherein the electrical resistance of the TMR sensor increases when magnetization directions of the pin layer and free layer are anti-parallel.

14. The device of claim 13, wherein the dopant comprising any of: hafnium (Hf), Ta, Yttrium (Y), zirconium (Zr), niobium (Nb), molybdenum (Mo), tungsten (W), titanium (Ti), and/or silicon (Si).

15. The device of claim 14, wherein the composition of the dopant can range between 0-20 percent of the free layer.

16. The device of claim 13, wherein the barrier layer comprises an electrical insulating material.

17. The device of claim 16, wherein the barrier layer comprises any of magnesium oxide (MgO), aluminum oxide (AlOx), titanium oxide (TiOx), and/or zinc oxide (ZnOx).

18. The device of claim 13, wherein the device is a tunneling magneto-resistive (TMR) sensor configured to be part of a hard disk drive system.
